(19) United States
(12) Patent Application Publication
(10) Pub. No.: US 2011/0207311 A1
(43) Pub. Date: Aug. 25, 2011

(54) Method of Manufacturing Semiconductor Device

(75) Inventors: Seung Woo Han, Seoul (KR); Young Mee Kang, Gyeonggi-do (KR)

(73) Assignee: HYNIX SEMICONDUCTOR INC., Icheon-si (KR)

(21) Appl. No.: 13/033,357

(22) Filed: Feb. 23, 2011

(30) Foreign Application Priority Data
Feb. 25, 2010 (KR) 10-2010 17053

(51) Int. Cl. H01L 21/28

(52) U.S. Cl. 438/585; 257/E21.158

(57) ABSTRACT

A method of manufacturing a semiconductor device may include sequentially forming a tunnel insulating layer, a first conductive layer, a dielectric layer, and a second conductive layer over a semiconductor substrate, forming hard mask patterns on the second conductive layer, forming a passivation layer on surfaces of the hard mask patterns, and etching the second conductive layer, the dielectric layer, and the first conductive layer using the hard mask patterns and the passivation layer as an etch mask.

### CROSS-REFERENCE TO RELATED APPLICATION

Priority to Korean patent application number 10-2010-0017053 filed on Feb. 25, 2010, the entire disclosure of which is incorporated by reference herein, is claimed.

### BACKGROUND

An exemplary embodiment relates generally to a method of manufacturing a semiconductor device and, more particularly, to a method of manufacturing a semiconductor device for forming target patterns.

Transistors or gate patterns of memory cells are formed or metal lines are formed, using an etch process to patterning a conductive layer that is formed over a semiconductor substrate. For example, hard mask patterns are formed on the conductive layer, and the conductive layer is etched by an etch process using the hard mask patterns as an etch mask, thereby forming the gate patterns or conductive patterns, such as metal lines. If an interval (i.e., a space) between the conductive patterns is narrower than a target interval, failure may be generated. In order to secure the target interval, each of the conductive patterns must have a target width. Thus, with the sidewalls of the conductive patterns becoming vertical with respect to the semiconductor substrate, a sufficient interval can be secured between the conductive patterns. However, the sidewalls of the conductive patterns may be inclined because of various causes generated during etch processes. Consequently, the width of the conductive pattern is increased, and an interval between the conductive patterns is narrowed.

FIGS. 1A to 1C are cross-sectional views illustrating a known method of forming the gates of a NAND flash memory device.

Referring to FIG. 1A, there is provided a semiconductor substrate 100 on which a tunnel insulating layer 102, a charge trap layer 104, a dielectric layer 106, and a conductive layer 108 are consecutively stacked. The charge trap layer 104 is used as floating gates, and the conductive layer 108 is used as control gates. Meanwhile, the dielectric layer 106 and the conductive layer 108 may be formed by patterning the charge trap layer 104 in a direction of bit lines.

Hard mask patterns 110 are formed on the conductive layer 108 by forming a hard mask layer, typically comprising oxides, on the conductive layer 108 and patterning the hard mask layer in a direction of word lines crossing the bit lines.

Referring to FIG. 1B, the conductive layer 108 is etched by an etch process using the hard mask patterns 110 as an etch mask to form conductive patterns 108a. The conductive patterns 108a become control gates.

The conductive layer 108 is etched using an etch gas, having a selectively higher etch rate for the conductive layer 108 than for the hard mask patterns 110 or the dielectric layer 106. During etching of the conductive layer 108, polymers 112 are generated. The polymers 112 are not removed by the etch gas used to etch the conductive layer 108 and are adsorbed on a surface of the hard mask patterns 110 and the sidewalls of the conductive layer 108. Like the hard mask patterns 110, the polymers 112 also function as an etch mask for the conductive layer 108. Thus, the conductive layer 108 is not etched at portions on which the polymers 112 are adsorbed.

When the polymers 112 are adsorbed on the sidewalls of the conductive layer 108 as described above, an exposed portion of the conductive layer 108 is narrowed and a region from which the conductive layer 108 is etched is also narrowed. Consequently, the sidewalls of the conductive layer 108 are etched with an inclination, and the conductive layer pattern 108a has a bottom width wider than a top width.

Referring to FIG. 1C, the dielectric layer 106 and the charge trap layer 104 are sequentially etched by an etch process using the hard mask patterns 110 as an etch mask to form dielectric layer patterns 106a and charge trap layer patterns 104a.

When the dielectric layer 106 and the charge trap layer 104 are etched, the polymers 112 remaining on the sidewalls of the conductive pattern 108a having a wide bottom width function as an etch mask. For this reason, an interval between the dielectric layer patterns 106a and an interval between the charge trap layer patterns 104a are narrowed or, in a worse case, the neighboring charge trap layer patterns 104a may be interconnected.

It becomes difficult to control an interval between gate stack patterns because of polymers generated when the exposed portions of a gate stack layer (for example, the charge trap layer, the conductive layer, and the dielectric layer) are etched by an etch process using the hard mask patterns as an etch mask to form the gate stack patterns as described above.

Furthermore, the number of processes is increased because the conductive layer 108, the dielectric layer 106, and the charge trap layer 104 are etched by different etch processes.

### BRIEF SUMMARY

An exemplary embodiment of this disclosure can prevent an interval between conductive layer patterns or an interval between stack layer patterns from becoming narrower than a target interval in an etch process for forming the conductive layer patterns or the stack layer patterns.

Furthermore, an exemplary embodiment of this disclosure can reduce the number of processes by patterning a stack layer, including a conductive layer, using a single process.

According to an aspect of this disclosure, there is provided a method of manufacturing a semiconductor device, including sequentially forming a tunnel insulating layer, a first conductive layer, a dielectric layer, and a second conductive layer over a semiconductor substrate, forming hard mask patterns on the second conductive layer, forming a passivation layer on surfaces of the hard mask patterns, and removing the second conductive layer, the dielectric layer, and the first conductive layer, exposed by the hard mask patterns, preferably using a single process.

According to another aspect of this disclosure, there is provided a method of manufacturing a semiconductor device, including sequentially forming a tunnel insulating layer, a first conductive layer, a dielectric layer, and a second conductive layer over a semiconductor substrate, forming hard mask patterns on the second conductive layer, etching the second conductive layer exposed by the hard mask patterns, preferably using an HBr gas, and removing the second conductive layer, the dielectric layer, and the first conductive layer exposed between the hard mask patterns, preferably using an etch gas comprising a chlorinated gas and a fluorine-containing gas. When the conductive layer is etched using the preferred HBr gas, a passivation layer is formed on the surfaces of the hard mask patterns.

According to yet another aspect of this disclosure, there is provided a method of manufacturing a semiconductor device, including forming a conductive layer over a semiconductor substrate, forming hard mask patterns on the conductive layer, forming a passivation layer on surfaces of the hard mask patterns, and patterning the conductive layer using the etch gas, preferably comprising a chlorinated gas and a fluorine-containing gas, by using the passivation layer and the hard mask patterns as an etch mask.

In the above aspects, the conductive layers preferably comprise polysilicon.

In the above aspects, the passivation layer preferably comprises a polymer.

In the above aspects, the passivation layer preferably is formed in such a manner than polymers generated by a reaction of the etch gas and the conductive layer exposed between the hard mask patterns, are adsorbed on the surfaces of the hard mask patterns.

In the above aspects, when the passivation layer is formed, a He gas and an O₂ gas preferably added to HBr gas.

In the above aspects, the thickness of the passivation layer is reduced in direct relationship to an increase in the amount of the He gas and the O₂ gas supplied.

In the above aspects, the hard mask patterns preferably comprise oxide materials.

In the above aspects, the hard mask patterns preferably comprise SiON.

In the above aspects, the second conductive layer, the dielectric layer, and the first conductive layer preferably are removed by a single process using an etch gas, preferably including a chlorinated gas and a fluorine-containing gas.

In the above aspects, the chlorinated gas preferably comprises Cl₂ gas, and the fluorine-containing gas preferably comprises NF₃ gas or SF₄ gas.

In the above aspects, the etch gas preferably further comprises HBr gas.

### BRIEF DESCRIPTION OF THE DRAWINGS

FIGS. 1A to 1C are cross-sectional views illustrating a known method of forming the gates of a NAND flash memory device; and

FIGS. 2A to 2D are cross-sectional views illustrating a method of forming the gates of a NAND flash memory device according to an exemplary embodiment of this disclosure.

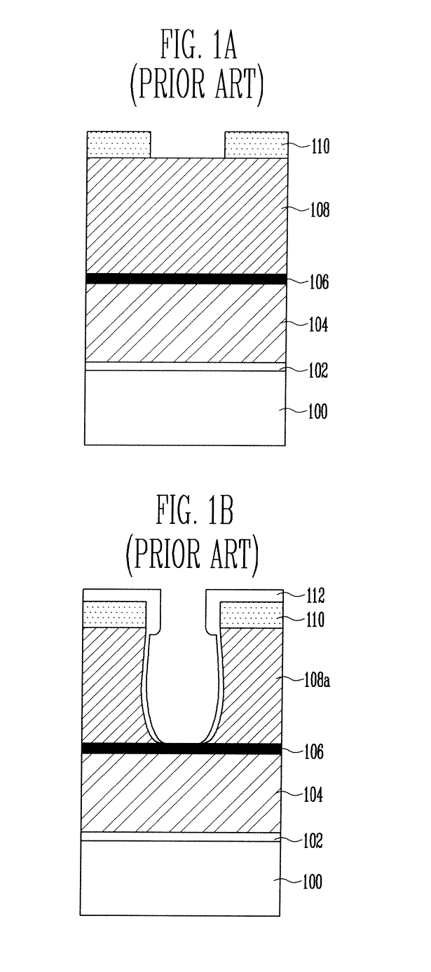

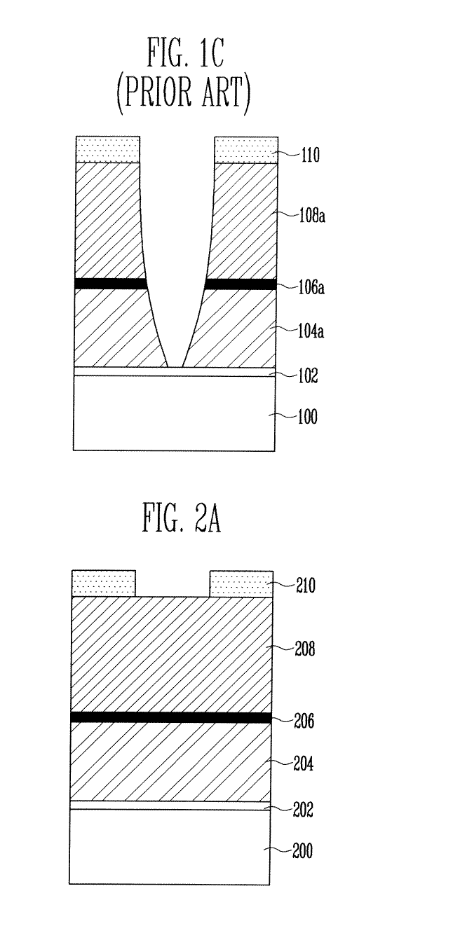

### DESCRIPTION OF EMBODIMENT

Hereinafter, an exemplary embodiment of the disclosure is described in detail with reference to the accompanying drawings. The drawing figures are provided to allow those having ordinary skill in the art to understand the scope of the exemplary embodiment of the disclosure.

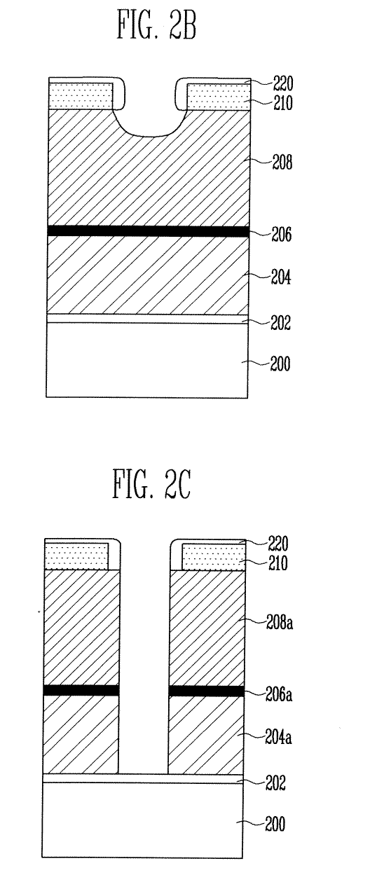

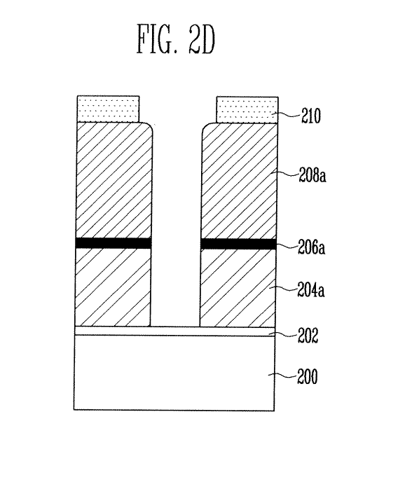

FIGS. 2A to 2D are cross-sectional views illustrating a method of forming the gates of a NAND flash memory device according to an exemplary embodiment of this disclosure.

Referring to FIG. 2A, a stack layer (202, 204, 206, and 208), including a conductive layer 208, is formed over a semiconductor substrate 200. Where gate patterns of the NAND flash memory device are formed, the stack layer may include a tunnel insulating layer 202, a charge trap layer 204, a dielectric layer 206, and a conductive layer 208.

The charge trap layer 204 is used as floating gates and may comprise a conductive layer. The charge trap layer 204 preferably comprises an amorphous silicon layer, a polysilicon layer, or a stack layer of an amorphous silicon layer and a polysilicon layer.

The conductive layer 208 is used as control gates and preferably comprises a stack structure of a polysilicon layer and a metal layer or a stack structure of a polysilicon layer and a metal silicide layer. Meanwhile, the dielectric layer 206 and the conductive layer 208 preferably are formed after patterning the charge trap layer 204 in the direction of bit lines.

Hard mask patterns 210 are formed on the conductive layer 208. The hard mask patterns 210 preferably are formed by forming a hard mask layer including oxides, such as SiON, and patterning the hard mask layer in the direction of word lines that cross the direction of the bit lines.

Referring to FIG. 2B, a passivation layer 220 is formed on surfaces of the hard mask patterns 210. The reason why the passivation layer 220 is formed is described below. In a subsequent etch process of patterning the conductive layer 208, an etch gas that does not generate polymers is used. If the etch gas that does not generate polymers is used, the hard mask patterns 210 may be etched by the etch gas according to materials forming the hard mask patterns 210. The passivation layer 220 is formed to protect the hard mask patterns 210 in the etch process of the conductive layer.

The passivation layer 220 preferably is formed using an HBr gas. When the HBr gas is supplied, the HBr gas reacts with the conductive layer 208 exposed between the hard mask patterns 210 to generate polymers (e.g., silicon oxide bromide). The polymers are adsorbed on surfaces of the hard mask patterns 210. The polymers adsorbed on the surfaces of the hard mask patterns 210 form the passivation layer 220. Although the exposed portion of the conductive layer 208 may be etched by the reaction of the conductive layer 208 and the HBr or other gas, an etched thickness is very thin.

Meanwhile, when the passivation layer 220 is formed on the surfaces of the hard mask patterns 210, the exposed region of the conductive layer 208 is narrowed by the passivation layer 220. In this case, if the width of the hard mask pattern 210 formed is narrower than a target width, a reduction in the exposed region of the conductive layer 208 can be prevented.

When the passivation layer 220 is formed, an He gas and an O₂ gas preferably are added to the HBr gas to control the thickness of the passivation layer 220 formed on the surfaces of the hard mask patterns 210. For example, if the quantity of supply of the He gas and the O₂ gas added to the HBr gas is increased, the thickness of the passivation layer 220, formed on tops and sides of the hard mask patterns 210, can be reduced. This is because if the quantity of supply of the He gas and the O₂ gas added to the HBr gas is increased, deposition of the passivation layer 220 is reduced.

Referring to FIG. 2C, to form conductive layer patterns 208a, the exposed portions of the conductive layer 208 are etched by an etch process using the hard mask patterns 210 and the passivation layer 220 as an etch mask. When the conductive layer 208 is etched, an etch gas that does not generate polymers preferably is used. More particularly, the conductive layer 208 is etched using the etch gas, preferably including a chlorinated gas and a fluorine-containing gas. Cl₂ preferably is used as the chlorinated gas, and an NF₃ or SF₃ gas preferably is used as the fluorine-containing gas. In the case where the conductive layer 208 made of polysilicon is etched, an HBr gas preferably is added to the chlorinated gas and the fluorine-containing gas to increase the etch rate. Polymers may be generated owing to the addition of the HBr gas, but are inhibited from being generated by the chlorinated gas and the fluorine-containing gas.

When the conductive layer 208 is etched using the etch gas, preferably including the chlorinated gas and the fluorine-containing gas, with the hard mask patterns 210 being exposed, the hard mask patterns 210 may be etched by the etch gas, thus not playing the role of an etch mask. However, the loss of the hard mask patterns 210 due to the etch gas can be prevented because the passivation layer 220 formed on the surfaces of the hard mask patterns 210 protects the hard mask patterns 210 from the etch gas used to etch the exposed portions of the conductive layer 208.

Since the conductive layer 208 is etched using the etch gas to prohibit the generation of the polymers, the sidewalls of the conductive layer patterns 208a becomes almost vertical (i.e., perpendicular) with respect to the horizontal semiconductor substrate 200. Accordingly, reduction in the interval between the conductive layer patterns 208a can be prevented. In other words, the top width and the bottom width of each of the conductive layer patterns 208a formed have the same target width.

Next, dielectric layer patterns 206a and charge trap layer patterns 204a are formed by etching the dielectric layer 206 and the charge trap layer 204. The dielectric layer 206 and the charge trap layer 204 preferably are etched using an etch process using the hard mask patterns 210 and the passivation layer 220 as an etch mask. In some embodiments, the dielectric layer 206 and the charge trap layer 204 may be etched using the etch gas used to etch the exposed portions of the conductive layer 208. Even in the case where the charge trap layer 204 comprises polysilicon, the generation of polymers is inhibited and a reduction in the interval between the charge trap layer patterns 204a accordingly can be prevented. Thus, the top width and the bottom width of the conductive layer pattern 208a can be formed to have the same target width. Accordingly, an interval between stack layer patterns can be sufficiently secured.

In this disclosure, as described above, the conductive layer 208, the dielectric layer 206, and the charge trap layer 204 preferably are etched through a one-stop process using the etch gas used to etch the exposed portions of the conductive layer 208. Accordingly, the process of forming patterns can be simplified.

Furthermore, the etch gas does not generate polymers during the process of etching the dielectric layer 206 and the charge trap layer 204.

Referring to FIG. 2D, the passivation layer formed on the surfaces of the hard mask patterns 210 may be removed using a subsequent process, such as a post-cleaning process, for example.

In the exemplary embodiment of this disclosure, as described above, the charge trap layer (or the conductive layer), the dielectric layer, and the conductive layer preferably are patterned by a single process using the hard mask patterns as an etch mask. Accordingly, the number of etch processes for patterning can be reduced.

Furthermore, in the exemplary embodiment of this disclosure, since the etch gas capable of prohibiting or inhibiting the generation of hard polymers is used, a phenomenon in which the polymers are formed during a process of etching a stack layer in order to form patterns can be improved. Accordingly, according to the present disclosure, the sidewalls of the patterns can be formed to have a vertical shape (i.e., a shape perpendicular to the semiconductor substrate surface).

Furthermore, according to the present disclosure, the passivation layer preferably is formed on the surfaces of the hard mask patterns using a reaction gas, before the process of etching the stack layer using the etch gas is performed. Accordingly, although the etch gas includes materials that may damage the hard mask patterns, a phenomenon in which the hard mask patterns are lost owing to the etch gas can be prevented because the hard mask patterns are blocked by the passivation layer.

Although the method of forming the gate patterns of the NAND flash memory device has been described as an example, the method may be applied to all processes of etching a conductive layer formed over a semiconductor substrate. The hard mask patterns, the passivation layer, and the process using the etch gas may be applied to, for example, a case where a single conductive layer for forming metal lines is etched.

As described above, in the exemplary embodiment of this disclosure, when a stack layer for forming stack layer patterns is etched, exposed portions of the stack layer are etched using an etch gas that does not generate polymers. Accordingly, a reduction in the interval between the stack layer patterns due to the generation of the polymers can be prevented. That is, the conductive layer or the stack layer can be etched so that the sidewalls of the patterns become almost vertical to the semiconductor substrate.

Furthermore, in the exemplary embodiment of this disclosure, the number of processes can be reduced because the stack layer including the conductive layer is patterned by a single process.

Furthermore, in the exemplary embodiment of this disclosure, the passivation layer is formed on surfaces of the hard mask patterns which are formed over the stack layer and are configured to function as an etch mask. Accordingly, the loss of the hard mask patterns due to an etch gas used to etch the stack layer can be prevented.

What is claimed is:

1. A method of manufacturing a semiconductor device, the method comprising:
sequentially forming a tunnel insulating layer, a first conductive layer, a dielectric layer, and a second conductive layer over a semiconductor substrate;
forming hard mask patterns on the second conductive layer;
forming a passivation layer on surfaces of the hard mask patterns; and
etching the second conductive layer, the dielectric layer, and the first conductive layer using the hard mask patterns and the passivation layer as an etch mask.

2. The method of claim 1, comprising forming the passivation layer by forming by-products on the surfaces of the hard mask patterns during etching the second conductive layer using the hard mask patterns as an etch mask.

3. The method of claim 2, comprising forming the by-products by etching the second conductive layer with an etch gas comprising HBr, He, and O₂.

4. The method of claim 1, comprising etching the second conductive layer, the dielectric layer, and the first conductive layer in a single process.

5. The method of claim 1, wherein the second conductive layer comprises polysilicon.

6. The method of claim 4, comprising etching the second conductive layer, the dielectric layer, and the first conductive layer in the single process with an etch gas comprising a chlorinated gas and a fluorine-containing gas.

7. The method of claim 6, wherein:
the chlorinated gas comprises a Cl₂ gas, and
the fluorine-containing gas comprises an NF₃ gas or an SF₄ gas.

8. The method of claim 7, comprising adding an HBr gas to the etch gas.

9. A method of manufacturing a semiconductor device, the method comprising:
forming a conductive layer over a semiconductor substrate;
forming hard mask patterns on the conductive layer;
forming a passivation layer on surfaces of the hard mask patterns; and
patterning the conductive layer by using the passivation layer and the hard mask patterns as an etch mask.

10. The method of claim 9, comprising forming the passivation layer by forming by-products on the surfaces of the hard mask patterns during etching the conductive layer using the hard mask patterns as etch mask.

11. The method of claim 10, comprising forming the passivation layer in such a manner that polymers generated by a reaction of an etch gas and the conductive layer exposed between the hard mask patterns are adsorbed on the surfaces of the hard mask patterns.

12. The method of claim 11, wherein the etch gas comprises an HBr gas, a He gas, and an O₂ gas.

13. The method of claim 12, wherein a thickness of the passivation layer is reduced in direct relationship to an increase in an amount of the He gas and the O₂ gas supplied.

14. The method of claim 9, comprising patterning the conductive layer by etching the conductive layer using an etch gas comprising a chlorinated gas and a fluorine-containing gas.

15. The method of claim 14, wherein:
the chlorinated gas comprises a Cl₂ gas, and
the fluorine-containing gas comprises an NF₃ gas or an SF₄ gas.

16. The method of claim 14, wherein the etch gas additionally comprises an HBr gas.

17. The method of claim 9, wherein the conductive layer comprises polysilicon.
